(19) United States
(12) Patent Application Publication
(10) Pub. No.: US 2025/0174564 A1
(43) Pub. Date: May 29, 2025

(54) SEMICONDUCTOR DEVICE

(71) Applicant: FUJI ELECTRIC CO., LTD., Kawasaki-shi (JP)

(72) Inventor: Kazuya OKADA, Matsumoto-city (JP)

(73) Assignee: FUJI ELECTRIC CO., LTD., Kawasaki-shi (JP)

(21) Appl. No.: 18/900,273

(22) Filed: Sep. 27, 2024

(30) Foreign Application Priority Data
Nov. 28, 2023 (JP) 2023-200380

(51) Int. Cl. H01L 23/538; H01L 23/00; H01L 23/49; H01L 25/065

(52) U.S. Cl. CPC H01L 23/5381; H01L 23/49; H01L 23/5386; H01L 23/5387; H01L 24/32; H01L 25/0655; H01L 2224/32225; H01L 2924/1711; H01L 2924/173

(57) ABSTRACT

A semiconductor device, including: a semiconductor chip including a main electrode on a front surface thereof; a first conductive plate having a first main surface with a chip area defined thereon, a rear surface of the semiconductor chip being bonded to the chip area; a second conductive plate provided adjacent to the first conductive plate in a plan view of the semiconductor device; a supporting part provided adjacent to the first conductive plate in the plan view, and insulated from the first conductive plate, the supporting part and the second conductive plate being on two opposite sides of the chip area; and a lead frame, which including a first bonding part bonded to the supporting part, a second bonding part bonded to the second conductive plate, and an electrode bonding part bonded to the main electrode of the semiconductor chip via a bonding member.

### CROSS-REFERENCE TO RELATED APPLICATION

This application is based upon and claims the benefit of priority of the prior Japanese Patent Application No. 2023-200380, filed on Nov. 28, 2023, the entire contents of which are incorporated herein by reference.

### BACKGROUND OF THE INVENTION

### 1. Field of the Invention

The embodiments discussed herein relate to a semiconductor device.

### 2. Background of the Related Art

There is a proposed semiconductor device that includes two semiconductor chips and a clip for connecting electrodes on the front surfaces of the two semiconductor chips (see, for example, Japanese Laid-open Patent Publication No. 2013-251500). There is another proposed semiconductor device that includes two power semiconductor chips disposed on a P potential lead and an inner lead for connecting individual electrodes on the front surfaces of the two power semiconductor chips and an AC potential lead (see, for example, Japanese Laid-open Patent Publication No. 2021-166215).

### SUMMARY OF THE INVENTION

According to an aspect, there is provided a semiconductor device, including a semiconductor chip including a main electrode on a front surface thereof; a first conductive plate having a first main surface with a chip area defined thereon, a rear surface of the semiconductor chip being bonded to the chip area; a second conductive plate provided adjacent to the first conductive plate in a plan view of the semiconductor device; a supporting part provided adjacent to the first conductive plate in the plan view, and being insulated from the first conductive plate, the supporting part and the second conductive plate being on two opposite sides of the chip area; and a lead frame, including a first bonding part bonded to the supporting part, a second bonding part bonded to the second conductive plate, and an electrode bonding part bonded to the main electrode of the semiconductor chip via a bonding member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a lateral view of the semiconductor device of the first embodiment;

FIG. 3 is a plan view of a semiconductor unit included in the semiconductor device of the first embodiment;

FIG. 4 is a first cross-sectional view of the semiconductor unit included in the semiconductor device of the first embodiment;

FIG. 5 is a second cross-sectional view of the semiconductor unit included in the semiconductor device of the first embodiment;

FIG. 6 is a flowchart illustrating a method for manufacturing the semiconductor device of the first embodiment;

FIG. 7 is a plan view of an insulated circuit board included in the semiconductor device of the first embodiment;

FIG. 8 illustrates a setting step included in the method for manufacturing the semiconductor device of the first embodiment;

FIG. 9 illustrates a first bonding step included in the method for manufacturing the semiconductor device of the first embodiment;

FIG. 10 is a plan view of a semiconductor unit included in a semiconductor device of a reference example;

FIG. 11 illustrates a setting step included in a method for manufacturing the semiconductor device of the reference example;

FIG. 12 illustrates a first bonding step included in the method for manufacturing the semiconductor device of the reference example;

FIG. 13 is a plan view of the semiconductor unit included in the semiconductor device of the first embodiment (Modification 1-1);

FIG. 14 is a cross-sectional view of the semiconductor unit included in the semiconductor device of the first embodiment (Modification 1-1);

FIG. 15 is a plan view of a semiconductor unit included in a semiconductor device of a second embodiment; and

FIG. 16 illustrates a first bonding step included in a method for manufacturing a semiconductor device of a third embodiment.

### DETAILED DESCRIPTION OF THE INVENTION

Several embodiments will be described below with reference to the accompanying drawings. In the following, the terms “front surface” and “top face” refer to the X-Y plane facing upward (the +Z direction) in a semiconductor device of the drawings. Similarly, the term “upper” refers to the upward direction (the +Z direction) of the illustrated semiconductor device. On the other hand, the terms “rear surface” and “bottom face” refer to the X-Y plane facing downward (the −Z direction) in the illustrated semiconductor device. Similarly, the term “lower” refers to the downward direction (the −Z direction) of the illustrated semiconductor device. These terms have the same orientational relationships in other drawings if needed. “High” and “upper” in position refer to upper positions (the +Z direction) in the illustrated semiconductor device. On the other hand, “low” and “lower” in position refer to lower positions (the in −Z direction) the illustrated semiconductor device. The terms “front surface”, “top face”, “upper”, “rear surface”, “bottom face”, “lower”, and “lateral surface” are simply expedient expressions used to specify relative positional relationships, and are not intended to limit the technical ideas of the embodiments described herein. For example, the terms “upper” and “lower” do not necessarily imply the vertical direction to the ground surface. That is, the “upper” and “lower” directions are not defined in relation to the direction of the gravitational force. In addition, the term “major component” in the following refers to a constituent having a concentration equal to 80 vol % or higher. The phrase “substantially the same” refers to where two or more things being compared have a difference of no more than +10%. In addition, the terms “perpendicular”, “orthogonal”, and “parallel” may also include substantially perpendicular, substantially orthogonal, and substantially parallel, as appropriate, which may include a margin of error of +10° or less.

### (a) FIRST EMBODIMENT

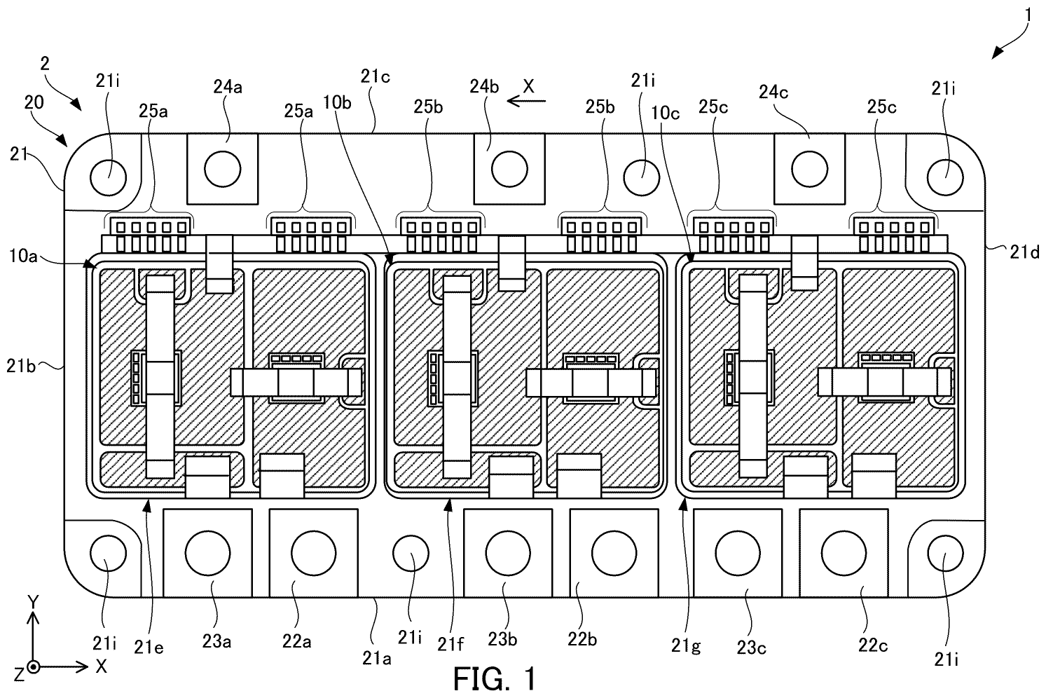

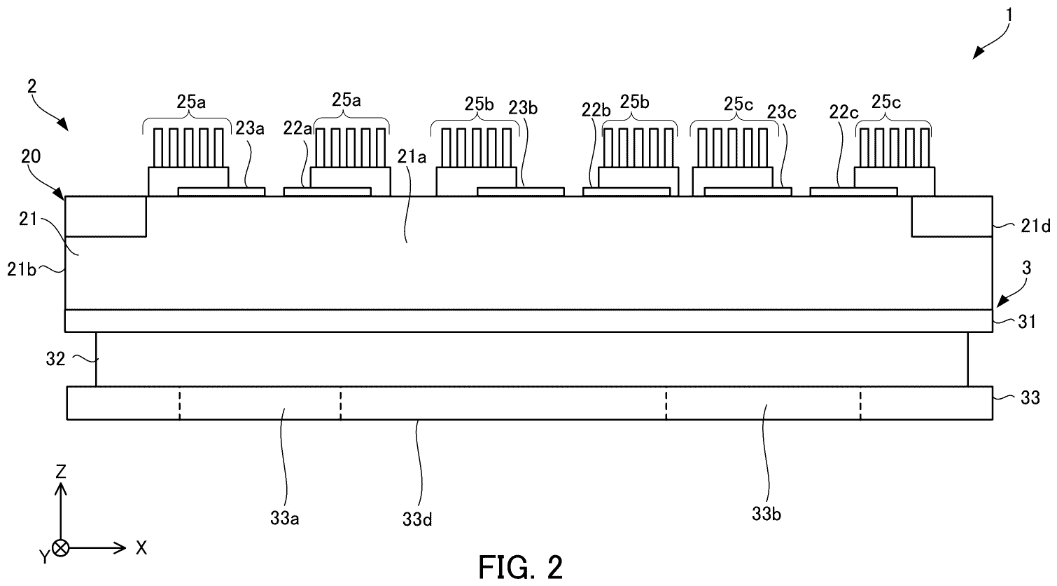

Next described is a semiconductor device 1 of a first embodiment with reference to FIGS. 1 and 2. FIG. 1 is a plan view of the semiconductor device according to the first embodiment. FIG. 2 is a lateral view of the semiconductor device of the first embodiment. Note that the lateral view of FIG. 2 is obtained when the X-Z plane is seen in the +Y direction in FIG. 1.

The semiconductor device 1 includes a

semiconductor module 2 and a cooling device 3. The semiconductor module 2 includes semiconductor units 10a, 10b, and 10c and a case 20 for housing the semiconductor units 10a, 10b, and 10c. The semiconductor units 10a, 10b, and 10c housed in the case 20 may be sealed with a sealing member (not illustrated).

Note that the semiconductor units 10a, 10b, and 10c all have the same configuration. Note that the term “semiconductor units 10” is used d in the following description when no distinction is made among the semiconductor units 10a, 10b, and 10c. Details of the semiconductor units 10 will be described later.

The case 20 includes a frame part 21; first connection terminals 22a, 22b, and 22c; second connection terminals 23a, 23b, and 23c; a U-phase output terminal 24a; a V-phase output terminal 24b; a W-phase output terminal 24c; and control terminals 25a, 25b, and 25c.

The frame part 21 has a substantially rectangular shape in plan view, and is surrounded on all four sides by outer walls 21a, 21b, 21c, and 21d. In plan view, the outer walls 21a and 21c correspond to the long sides of the frame part 21 while the outer walls 21b and 21d correspond to the short sides of the frame part 21. The corners at which the outer walls 21a, 21b, 21c, and 21d are connected to each other do not necessarily form right angles in plan view. They may be R-chamfered corners as illustrated in FIG. 1. Fixing holes 21i penetrating the frame part 21 are individually formed at each corner of the front surface of the frame part 21. Note that the fixing holes 21i provided in such corners of the frame part 21 may be located below (in the-Z direction) the front surface of the frame part 21.

The frame part 21 includes unit housing spaces 21e, 21f, and 21g disposed on the front surface along the outer walls 21a and 21c. The unit housing spaces 21e, 21f, and 21g are open and have a rectangular shape in plan view. The semiconductor units 10a, 10b, and 10c are housed in the unit housing spaces 21e, 21f, and 21g, respectively. The semiconductor units 10a, 10b, and 10c are individually bonded to a top plate 31 of the cooling device 3 to be described later. The frame part 21 is attached to the top plate 31 of the cooling device 3. When the frame part 21 is attached, the unit housing spaces 21e, 21f, and 21g of the frame part 21 surround (i.e., house) the semiconductor units 10a, 10b, and 10c, respectively, aligned on the cooling device 3. Note that an inlet 33a and an outlet 33b are formed on a bottom surface 33d (a surface opposite to the top plate 31 on which the semiconductor units 10 are disposed) of the cooling device 3. Details of the cooling device 3 will be described later.

In plan view, the frame part 21 has, on the outer wall 21a side of the front surface, the first connection terminals 22a, 22b, and 22c and the second connection terminals 23a, 23b, and 23c aligned along the outer wall 21a. A first end, which is an outer end, of each of the first connection terminals 22a, 22b, and 22c and the second connection terminals 23a, 23b, and 23c is exposed to the front surface on the outer wall 21a side. Their second ends, which are inner ends, individually emerge inside the unit housing spaces 21e, 21f, and 21g and are electrically connected to the semiconductor units 10a, 10b, and 10c. Note that the frame part 21 may accommodate nuts in locations individually facing openings of the first connection terminals 22a, 22b, and 22c and the second connection terminals 23a, 23b, and 23c on the front surface of the frame part 21 in such a manner that the nuts face these openings.

The frame part 21 also has, on the outer wall 21c side of the front surface, the U-phase output terminal 24a, the V-phase output terminal 24b, and the W-phase output terminal 24c aligned along the output wall 21c. First ends, which are outer ends, of the U-phase output terminal 24a, the V-phase output terminal 24b, and the W-phase output terminal 24c are exposed from the outer wall 21c. On the other hand, their second ends, which are inner ends, individually emerge inside the unit housing spaces 21e, 21f, and 21g and are electrically connected to the semiconductor units 10a, 10b, and 10c.

In this manner, on the front surface of the frame part 21, the first connection terminal 22a and the second connection terminal 23a are located across the unit housing space 21e from the U-phase output terminal 24a. In the same manner, the first connection terminal 22b and the second connection terminal 23b are located across the unit housing space 21f from the V-phase output terminal 24b, and the first connection terminal 22c and the second connection terminal 23c are located across the unit housing space 21g from the W-phase output terminal 24c.

Further, the frame part 21 has the control terminals 25a, 25b, and 25c disposed near the +Y direction sides of the unit housing spaces 21e, 21f, and 21g, respectively, along the outer wall 21c in plan view. Each set of the control terminals 25a, 25b, and 25c may be divided into two groups. The control terminals 25a, 25b, and 25c may have an L-shape, for example, and include outer ends and inner ends. The outer ends of the control terminals 25a, 25b, and 25c may extend vertically upward (in the +Z direction) from the front surface of the frame part 21. Their inner ends individually emerge inside the unit housing spaces 21e, 21f, and 21g. Note that the illustrated control terminals 25a, 25b, and 25c are merely an example, and appropriate changes may be made to their shape and number on an as-needed basis.

The frame part 21 includes the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c, as described above. The frame part 21 and these terminals are integrally formed by injection molding using a thermoplastic resin. As the thermoplastic resin, any of the following may be used, for example: a poly phenylene sulfide resin; a polybutylene terephthalate resin; a polybutylene succinate resin; a polyamide resin; and an acrylonitrile butadiene styrene resin.

The first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c are made of a metal with excellent electrical conductivity. Such a metal is, for example, copper, aluminum, or an alloy containing at least one of these as a major component. Plating may be applied to coat the surfaces of the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c. In this case, a material used for plating is, for example, nickel, a nickel-phosphorus alloy, or a nickel-boron alloy.

The sealing member (not illustrated) for sealing the unit housing spaces 21e, 21f, and 21g of the case 20 may be a thermosetting resin. The thermosetting resin is, for example, epoxy resin, phenolic resin, maleimide resin, or polyester resin; however, epoxy resin is preferred. A filler may be added to the sealing member. The filler may be a material with insulation properties and high thermal conductivity. The material is, for example, silicon oxide, aluminum oxide, boron nitride, or aluminum nitride.

The case 20 with the above-described configuration is merely an example. The case 20 simply needs to house the semiconductor units 10a, 10b, and 10c and realize a power conversion function using the semiconductor units 10a, 10b, and 10c.

The cooling device 3 includes the inlet 33a through which a refrigerant flows into the inside and the outlet 33b through which the refrigerant having circulated inside flows out to the outside. The cooling device 3 cools the semiconductor units 10 by discharging heat from the semiconductor units 10 via the refrigerant. Examples of the refrigerant used here include water, an antifreeze solution (ethylene glycol aqueous solution), and a long-life coolant. The cooling device 3 may include a pump and a heat dissipation device (radiator). The pump makes the refrigerant circulate by causing it to flow into the inlet 33a of the cooling device 3 and again causing the refrigerant that has flowed out from the outlet 33b to flow back into the inlet 33a. The heat dissipation device receives the refrigerant flowing out from the cooling device 3 and externally radiates heat of the refrigerant, to which heat of the semiconductor units 10 has been transferred.

The above-described cooling device 3 includes the top plate 31, a lateral wall 32 connected in a circular pattern to the rear surface of the top plate 31, and a cooling bottom plate 33 opposing the top plate 31 and connected to the rear surface of the lateral wall 32. The top plate 31 has a rectangular shape, surrounded on the four sides by long sides and short sides in plan view, and has a fastener hole in each of the four corners. Each corner of the top plate 31 may be R-chamfered in plan view. On the front surface of the top plate 31, the semiconductor units 10a, 10b, and 10c are bonded along the ±X direction. The lateral wall 32 is formed continuously in a circular pattern on the rear surface of the top plate 31. Multiple heat dissipation fins (not illustrated) are provided, on the rear surface of the top plate 31, in a region corresponding to the region where the semiconductor units 10a, 10b, and 10c are disposed.

The cooling bottom plate 33 has a flat plate-like shape, and has the same shape as the top plate 31 in plan view. That is, the cooling bottom plate 33 has a rectangular shape in plan view, as with the top plate 31. In addition, each corner of the cooling bottom plate 33 may also be R-chamfered. The cooling bottom plate 33 has a front surface and the bottom surface 33d that are parallel to each other. The bottom surface 33d of the cooling bottom plate 33 is flat with no difference in level and lies in the same plane. The bottom surface 33d of the cooling bottom plate 33 is provided with the inlet 33a and the outlet 33b through which the refrigerant flows in and out, respectively. Water distribution heads are attached to the inlet 33a and the outlet 33b via ring-shaped rubber packings in sealing areas (not illustrated) surrounding the inlet 33a and the outlet 33b. A water distribution pipe connected to the pump is attached to the water distribution heads.

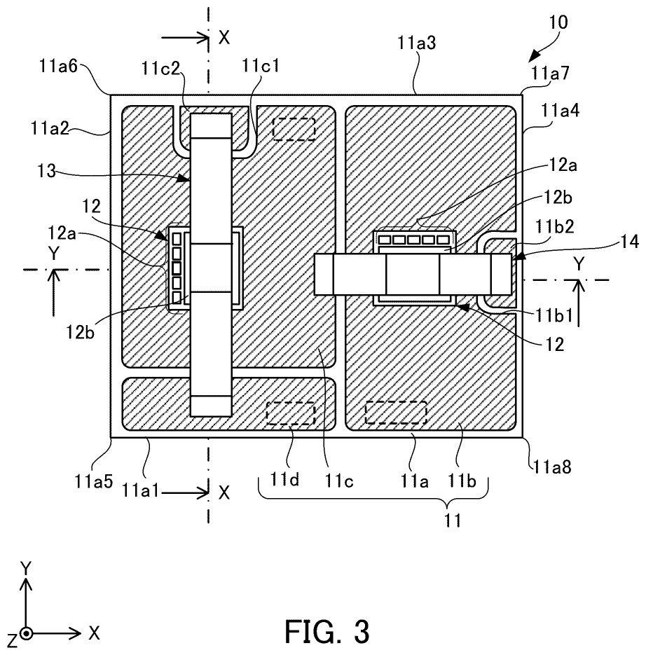

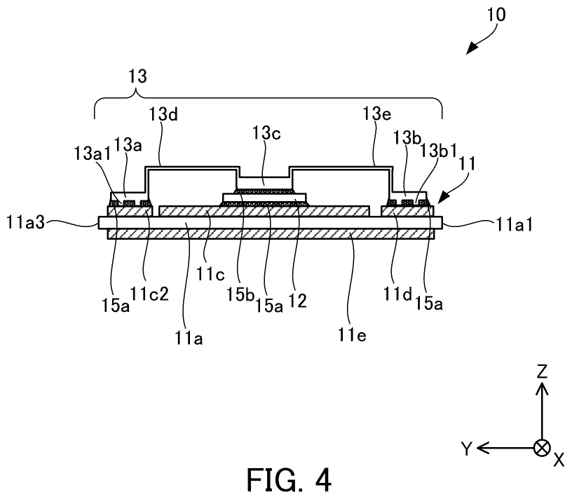

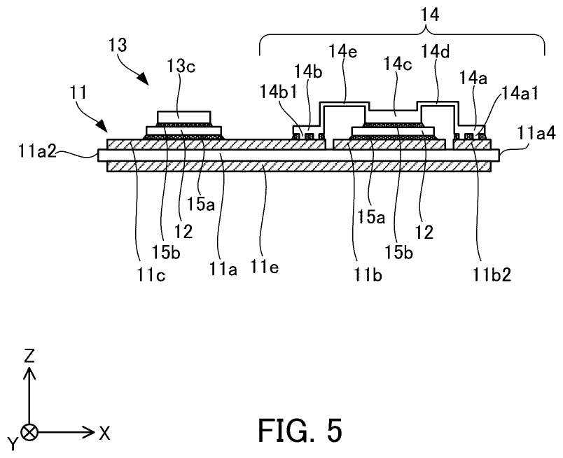

The semiconductor units 10 are described next with reference to FIGS. 3 to 5. FIG. 3 is a plan view of a semiconductor unit included in the semiconductor device of the first embodiment. FIGS. 4 and 5 are first and second cross-sectional views of the semiconductor unit included in the semiconductor device of the first embodiment. The cross sectional view of FIG. 4 is taken along the dashed-dotted line X-X of FIG. 3, and the cross sectional view of FIG. 5 is taken along the dashed-dotted line Y-Y of FIG. 3. To describe the configuration of the semiconductor unit 10, FIGS. 3 to 5 depict a case where there is no warpage.

Each semiconductor unit 10 includes an insulated circuit board 11, two semiconductor chips 12, and two lead frames 13 and 14. The semiconductor chips 12 are bonded to the insulated circuit board 11 via bonding members 15a. The lead frames 13 and 14 are bonded to main electrodes on the front surfaces of the semiconductor chips 12 and the insulated circuit board 11 via bonding members 15b.

The insulated circuit board 11 includes an insulating plate 11a, conductive plates 11b, 11c, and 11d, and a metal plate 11e, as illustrated in FIGS. 4 and 5. To the region indicated by the broken line on the conductive plate 11d in FIG. 3, the inner end of the second connection terminal 23a, 23b, or 23c is joined. Similarly, to the region indicated by the broken line on the conductive plate 11b in FIG. 3, the inner end of the first connection terminal 22a, 22b, or 22c is joined. Further, to the region indicated by the broken line on the conductive plate 11c in FIG. 3, the inner end of the U-phase output terminal 24a, the V-phase output terminal 24b, or the W-phase output terminal 24c is joined.

The insulating plate 11a and the metal plate 11e have a rectangular shape in plan view. The insulating plate 11a and the metal plate 11e may have R-or C-chamfered corners. The metal plate 11e is smaller in size than the insulating plate 11a in plan view, and is thus formed within the insulating plate 11a.

The insulating plate 11a includes lateral surfaces 11a1 to 11a4 that sequentially surround the front surface on all four sides. The lateral surfaces 11a1 and 11a3 correspond to the long sides of the insulating plate 11a in plan view while the lateral surfaces 11a2 and 11a4 correspond to the short sides of the insulating plate 11a in plan view. In addition, the insulating plate 11a includes four corners 11a5 to 11a8. The corner 11a5 is formed by the lateral surfaces 11a1 and 11a2. The corner 11a6 is formed by the lateral surfaces 11a2 and 11a3. The corner 11a7 is formed by the lateral surfaces 11a3 and 11a4. The corner 11a8 is formed by the lateral surfaces 11a4 and 11a1.

The insulating plate 11a with the above-described configuration is made of a material with high insulation and excellent thermal conductivity. The insulating plate 11a may be made of ceramic. The ceramic here is, for example, aluminum oxide, aluminum nitride, or silicon nitride.

The conductive plates 11b, 11c, and 11d are formed on the front surface of the insulating plate 11a. The conductive plates 11b, 11c, and 11d are made of a metal with excellent electrical conductivity. The metal is, for example, copper, aluminum, or an alloy whose major component is at least one of these. Plating may be applied to coat the surfaces of the conductive plates 11b, 11c, and 11d in order to provide improved corrosion resistance. In this case, a material used for plating is, for example, nickel, a nickel-phosphorus alloy, or a nickel-boron alloy.

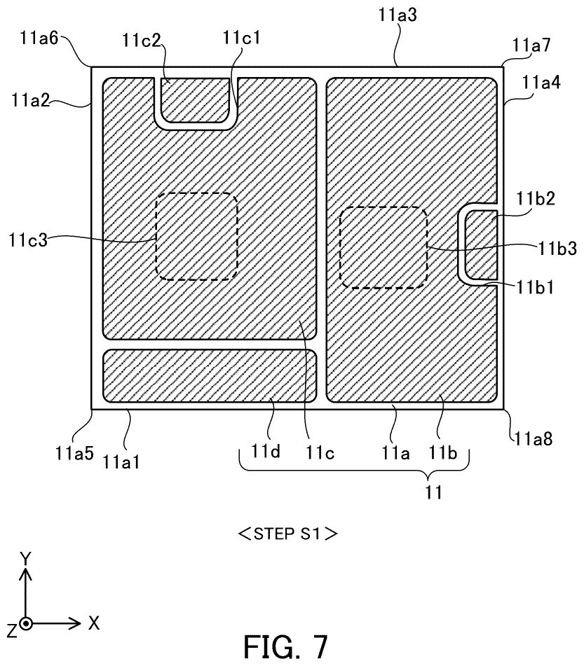

The conductive plate 11b occupies half the area of the front surface of the insulating plate 11a on the lateral surface 11a4 side, and spreads across the entire region spanning from the lateral surface 11a1 to the lateral surface 11a3. A chip area 11b3 (see FIG. 7) is defined on the front surface (one example of the first main surface) of the conductive plate 11b. The chip area 11b3 corresponds to the shape of the semiconductor chip 12 in plan view, and the semiconductor chip 12 is bonded to the chip area 11b3.

In addition, the inner end of the first connection terminal 22a, 22b, or 22c is joined to the region indicated by the broken line on the front surface of the conductive plate 11b in FIG. 3, located in the −X direction on the front surface and near the-Y direction edge thereof. To bond the inner end of the first connection terminal 22a, 22b, or 22c to the broken line region on the conductive plate 11b, a bonding member, laser welding, or ultrasonic bonding may be used. Alternatively, this bonding may be achieved using a conductive block body interposed therebetween.

The conductive plate 11b also includes a

supporting conductive plate 11b2 which is provided on the opposite side (the +X direction side) of the chip area 11b3 (the semiconductor chip 12) from the conductive plate 11c and insulated from the conductive plate 11b.

In the case of FIG. 3, the conductive plate 11b has a recess 11b1 formed on the edge of the opposite side (the +X direction side) of the chip area 11b3 (the semiconductor chip 12) from the conductive plate 11c. The recess 11b1 may oppose the chip area 11b3 (the semiconductor chip 12). In particular, the recess 11b1 faces the chip area 11b3 (the semiconductor chip 12) in the +X direction. The recess 11b1 is a region where a part of the +X direction edge of the conductive plate 11b is recessed in the −X direction. The shape of the recess 11b1 in plan view may be U-shaped, semicircular, or rectangular, for example. FIG. 3 depicts a case where the recess 11b1 is U-shaped.

The supporting conductive plate 11b2 may be made of, for example, the same material as the conductive plate 11b. The supporting conductive plate 11b2 is provided in the recess 11b1 of the conductive plate 11b. That is, the supporting conductive plate 11b2 is formed on the insulating plate 11a without being in contact with the conductive plate 11b. Therefore, the supporting conductive plate 11b2 and the conductive plate 11b are electrically insulated from each other. The shape and size of the supporting conductive plate 11b2 in plan view may be such that the supporting conductive plate 11b2 could be placed in the recess 11b1 and include an end part (a wire bonding part 14a) of the lead frame 14 to be described later. In the case of FIG. 3, the supporting conductive plate 11b2 corresponds to the shape of the recess 11b1. The width of the supporting conductive plate 11b2 in the +Y direction is wider than the width of the lead frame 14 in the same direction.

Note that the supporting conductive plate 11b2 with the above configuration does not necessarily need to be provided at the +X direction edge of the conductive plate 11b. The supporting conductive plate 11b2 simply needs to be provided, on the conductive plate 11b, on the opposite side (the +X direction side) of the chip area 11b3 (the semiconductor chip 12) from the conductive plate 11c. For example, the supporting conductive plate 11b2 may be disposed, on the conductive plate 11b, between the chip area 11b3 (the semiconductor chip 12) and the +X direction edge of the conductive plate 11b. In this case, the conductive plate 11b does not need to have the recess 11b1 but may have an opening region formed at a position corresponding to the supporting conductive plate 11b2. The opening region in this case may also have a shape and size such that the supporting conductive plate 11b2 is not in contact with the conductive plate 11b.

The conductive plate 11c occupies half the area of the front surface of the insulating plate 11a on the lateral surface 11a2 side. The conductive plate 11c also extends from the lateral surface 11a3 side of the front surface of the insulating plate 11a to just short of the lateral surface 11a1. A chip area 11c3 (see FIG. 7) is provided on the front surface of the conductive plate 11c. The chip area 11c3 corresponds to the shape of the semiconductor chip 12 in plan view, and the semiconductor chip 12 is bonded to the chip area 11c3. In addition, the inner end of the U-phase output terminal 24a, the V-phase output terminal 24b, or the W-phase output terminal 24c is joined to the region indicated by the broken line on the front surface of the conductive plate 11c in FIG. 3, located in the +X direction on the front surface and near the +Y direction edge thereof. Note here that the broken line region is provided on the +X direction side (the conductive plate 11b side) of a supporting conductive plate 11c2 (a recess 11c1) to be described below. To bond the inner end of the U-phase output terminal 24a, the V-phase output terminal 24b, or the W-phase output terminal 24c to the broken line region on the conductive plate 11c, a bonding member, laser welding, or ultrasonic bonding may be used. Alternatively, this bonding may be achieved using a conductive block body interposed therebetween.

In addition, the conductive plate 11c also includes the supporting conductive plate 11c2, which is provided on the opposite side (the +Y direction side) of the chip area 11c3 (the semiconductor chip 12) from the conductive plate 11d and electrically insulated from the conductive plate 11c.

In the case of FIG. 3, the conductive plate 11c has the recess 11c1 formed on the edge of the opposite side (the +Y direction side) of the chip area 11c3 (the semiconductor chip 12) from the conductive plate 11d. The recess 11c1 may oppose the chip area 11c3 (the semiconductor chip 12). In particular, in this case, the recess 11c1 faces the chip area 11c3 (the semiconductor chip 12) in the +Y direction. The recess 11c1 is a region where a part of the +Y direction edge of the conductive plate 11c is recessed in the −Y direction. The shape of the recess 11c1 in plan view may be U-shaped, semicircular, or rectangular, for example. FIG. 3 depicts a case where the recess 11c1 is U-shaped.

The supporting conductive plate 11c2 may be made of, for example, the same material as the conductive plate 11c. The supporting conductive plate 11c2 is provided in the recess 11c1 of the conductive plate 11c. That is, the supporting conductive plate 11c2 is formed on the insulating plate 11a without being in contact with the conductive plate 11c. Therefore, the supporting conductive plate 11c2 and the conductive plate 11c are electrically insulated from each other. The shape and size of the supporting conductive plate 11c2 in plan view may be such that the supporting conductive plate 11c2 could be placed in the recess 11c1 and include an end part (a wire bonding part 13a) of the lead frame 13 to be described later. In the case of FIG. 3, the supporting conductive plate 11c2 corresponds to the shape of the recess 11c1. The width of the supporting conductive plate 11c2 in the +X direction is wider than the width of the lead frame 13 in the same direction.

Note that the supporting conductive plate 11c2 with the above configuration does not necessarily need to be provided at the +Y direction edge of the conductive plate 11c. The supporting conductive plate 11c2 simply needs to be provided, on the conductive plate 11c, on the opposite side (the +Y direction side) of the chip area 11c3 (the semiconductor chip 12) from the conductive plate 11d. For example, the supporting conductive plate 11c2 may be disposed, on the conductive plate 11c, between the chip area 11c3 (the semiconductor chip 12) and the +Y direction edge of the conductive plate 11c. In this case, the conductive plate 11c does not need to have the recess 11c1 but may have an opening region formed at a position corresponding to the supporting conductive plate 11c2. The opening region in this case may also have a shape and size such that the supporting conductive plate 11c2 is not in contact with the conductive plate 11c.

The conductive plate 11d occupies, on the front surface of the insulating plate 11a, an area surrounded by the conductive plates 11b and 11c. The width of the conductive plate 11d in the +X direction is equal to the width of the conductive plate 11c in the same direction. The region indicated by the broken line on the conductive plate 11d is where the inner end of the second connection terminal 23a, 23b, or 23c is bonded. To bond the inner end of the second connection terminal 23a, 23b, or 23c to the broken line region on the conductive plate 11d, a bonding member, laser welding, or ultrasonic bonding may be used. Alternatively, this bonding may be achieved using a conductive block body interposed therebetween.

The conductive plates 11b, 11c, and 11d described above are formed on the front surface of the insulating plate 11a as follows. For example, a metal layer is formed on the front surface of the insulating plate 11a and then subjected to etching or the like, to thereby obtain the conductive plates 11b, 11c, and 11d with predetermined shapes. Further, the periphery of a predetermined area on each of the conductive plates 11b and 11c may be peeled off by etching to form the supporting conductive plates 11b2 and 11c2, which are separated from the conductive plates 11b and 11c, respectively.

Alternatively, the conductive plates 11b and 11c including the recesses 11b1 and 11c1 and the conductive plate 11d, which are preliminarily cut out of a metal layer, may be pressure bonded to the front surface of the insulating plate 11a, and then the supporting conductive plates 11b2 and 11c2 may be pressure bonded into the recesses 11b1 and 11c1, respectively.

The conductive plates 11b, 11c, and 11d may have R-or C-chamfered corners. Note that the conductive plates 11b, 11c, and 11d are merely an example, and appropriate changes may be made to the number of the conductive plates 11b, 11c, and 11d, their shapes, sizes and locations on an as-needed basis.

The metal plate 11e is formed on the rear surface of the insulating plate 11a, as illustrated in FIGS. 4 and 5. The metal plate 11e has a rectangular shape. The area of the metal plate 11e in plan view is smaller than that of the insulating plate 11a, but larger than the area of the region where the conductive plates 11b, 11c, and 11d are formed. The metal plate 11e may have R- or C-chamfered corners. The metal plate 11e is smaller in size than the insulating plate 11a, and is formed on the entire surface of the insulating plate 11a except for the edges. The metal plate 11e is made of a metal with excellent thermal conductivity. The metal is, for example, copper, aluminum, or an alloy including at least one of these. In order to provide improved corrosion resistance, plating may be applied to coat the surface of the metal plate 11e. In this case, a material used for plating is, for example, nickel, a nickel-phosphorus alloy, or a nickel-boron alloy.

As the insulated circuit board 11 having the above-described configuration, for example, a direct copper bonding (DCB) board or an active metal brazed (AMB) board may be used. The insulated circuit board 11 may be attached to the front surface of the cooling device 3 via a bonding member (not illustrated). This allows heat generated in the semiconductor chips 12 to be conducted to the cooling device 3 via the conductive plates 11b and 11c, the insulating plate 11a, and the metal plate 11e and then radiated outwards.

The bonding members 15a and 15b are, for example, solder. The solder used is lead-free solder. The lead-free solder may contain, as a major component, an alloy containing at least two selected from tin, copper, zinc, antimony, indium, and bismuth, for example. Further, the solder may include an additive, such as nickel, germanium, cobalt, or silicon. The inclusion of the additive increases wettability, brightness, and bond strength of the solder, which results in improved reliability.

The bonding member (not illustrated) for joining the semiconductor units 10 and the cooling device 3 may be solder, a brazing material, or a thermal interface material. The solder used is lead-free solder. The brazing material used may contain, as a major component, at least one selected from an aluminum alloy, a titanium alloy, a magnesium alloy, a zirconium alloy, and a silicon alloy, for example. The thermal interface material used is an adhesive material including, for example, an elastomer sheet, room temperature vulcanization (RTV) rubber, gel, and a phase change material. Attachment of the semiconductor units 10 to the cooling device 3 via the foregoing brazing material or thermal interface material improves heat dissipation of the semiconductor units 10.

Each of the semiconductor chips 12 includes a power device element. The power device element is a reverse-conducting insulated gate bipolar transistor (RC-IGBT) containing silicon as a major component. The RC-IGBT has integrated functions of both an IGBT, which is a switching element, and a free wheeling diode (FWD), which is a diode element. Control electrodes 12a (a gate electrode) and an output electrode (an emitter electrode), which is a main electrode 12b, are provided on the front surface of the semiconductor chip 12. An input electrode (a collector electrode) (not illustrated), which is a main electrode, is provided on the rear surface of the semiconductor chip 12. Note that the control electrodes 12a are laid out along one side of the front surface of the semiconductor chip 12 (or at the center of the one side). The output electrode is disposed at the front surface of the semiconductor chip 12. The input electrode is disposed occupying the center of the rear surface of the semiconductor chip 12.

Another power device element that may be used is a power metal oxide semiconductor field effect transistor (power MOSFET) whose major component is silicon carbide. In a power MOSFET, a body diode may function as an FWD. Such a semiconductor chip 12 has the control electrodes 12a (a gate electrode) and an output electrode (a source electrode) functioning as the main electrode 12b on the front surface, and an input electrode (a drain electrode) functioning as a main electrode on the rear surface.

The lead frame 13 electrically connects the main electrode 12b of the semiconductor chip 12 on the conductive plate 11c to the conductive plate 11d to make a wiring connection. The lead frame 14 electrically connects the main electrode 12b of the semiconductor chip 12 on the conductive plate 11b to the conductive plate 11c to make a wiring connection. The semiconductor unit 10 may be a device that serves as a single-phase inverter circuit.

The lead frames 13 and 14 include the wire bonding parts 13a and 14a (first bonding parts), electrode bonding parts 13c and 14c, and wire bonding parts 13b and 14b (second bonding parts), as illustrated in FIGS. 4 and 5. Note that the wire bonding parts 13a and 14a are examples of the first bonding part while the wire bonding parts 13b and 14b are examples of the second bonding part. The lead frames 13 and 14 further include linking parts 13d and 14d for linking the wire bonding parts 13a and 14a and the electrode bonding parts 13c and 14c and linking parts 13e and 14e for linking the electrode bonding parts 13c and 14c and the wire bonding parts 13b and 14b, respectively. The lead frames 13 and 14 integrally include these parts and are linear shaped in plan view. Each of the lead frames 13 and 14 may have the same width over its entire length in plan view. The wire bonding parts 13a and 14a, the electrode bonding parts 13c and 14c, and the wire bonding parts 13b and 14b may be of the same, uniform thickness (in the +Z direction) throughout. In addition, the linking parts 13e and 14e and the linking parts 13d and 14d may be of the same, uniform thickness throughout, and may be thinner in thickness than the wire bonding parts 13a and 14a, the electrode bonding parts 13c and 14c, and the wire bonding parts 13b and 14b.

The wire bonding parts 13a and 14a are joined to the supporting conductive plates 11c2 and 11b2, respectively, via the bonding members 15a. The wire bonding parts 13a and 14a have, for example, a flat plate-like shape. The shape and size of the wire bonding parts 13a and 14a in plan view may be such that the wire bonding parts 13a and 14a could fit in the supporting conductive plates 11c2 and 11b2, respectively. Multiple bosses 13a1 and 14a1 may be formed on the rear surfaces of the wire bonding parts 13a and 14a. Each of these bosses 13a1 and 14a1 may have, for example, a cylindrical or polygonal shape. The heights of the bosses 13a1 and 14a1 are substantially uniform. The bosses 13a1 and 14a1 are able to maintain the thicknesses of the bonding members 15a between the wire bonding parts 13a and 14a and the supporting conductive plates 11c2 and 11b2 approximately constant.

Each of the electrode bonding parts 13c and 14c is bonded to the main electrode 12b of the corresponding semiconductor chip 12 via a bonding member 15b. The electrode bonding parts 13c and 14c have, for example, a flat plate-like shape. The electrode bonding parts 13c and 14c may have a shape and size corresponding to the main electrodes 12b of the semiconductor chips 12 in plan view. No bosses may be formed on the rear surfaces of the electrode bonding parts 13c and 14c.

The wire bonding parts 13b and 14b are joined to the conductive plates 11d and 11c, respectively, via the bonding members 15a. The wire bonding parts 13b and 14b have, for example, a flat plate-like shape. The shape and size of the wire bonding parts 13b and 14b may be such that the wire bonding parts 13b and 14b could fit in the conductive plates 11d and 11c, respectively. Multiple bosses 13b1 and 14b1 may be formed on the rear surfaces of the wire bonding parts 13b and 14b. Each of these bosses 13b1 and 14b1 may have, for example, a cylindrical or polygonal shape. The heights of the bosses 13b1 and 14b1 are substantially uniform. The bosses 13b1 and 14b1 are able to maintain the thicknesses of the bonding members 15a between the wire bonding parts 13b and 14b and the conductive plates 11d and 11c approximately constant.

The linking parts 13d and 14d have a flat plate-like shape. In plan view, the linking parts 13d and 14d integrally connect first ends of the wire bonding parts 13a and 14a, located closer to the electrode bonding parts 13c and 14c, and first ends of the electrode bonding parts 13c and 14c, located closer to the wire bonding parts 13a and 14a.

In lateral view, the linking parts 13d and 14d extend vertically upward (in the +Z direction) from the first ends of the wire bonding parts 13a and 14a, located closer to the electrode bonding parts 13c and 14c, to a predetermined height (first height), and bend at a right angle to the electrode bonding part 13c and 14c sides. Then, the linking parts 13d and 14d extend toward the electrode bonding parts 13c and 14c, bend above the first ends of the electrode bonding parts 13c and 14c, located closer to the wire bonding parts 13a and 13a, and extend vertically downward (in the −Z direction) to a predetermined height (third height) to connect to the first ends of the electrode bonding parts 13c and 14c. Note here that the first height is greater (i.e., higher) than the third height, and is also greater than the combined length of the third height and the thickness of the semiconductor chip 12 (in the +Z direction). That is, the electrode bonding parts 13c and 14c are located higher in position (in the +Z direction) than the wire bonding parts 13a and 14a. The intermediate portions of the linking parts 13d and 14d are parallel to the main surface of the insulated circuit board 11. Note that the first height is a predetermined height from the wire bonding parts 13a and 14a to (the intermediate portions of) the linking parts 13d and 14d, and the third height is a predetermined height from the electrode bonding parts 13c and 14c to (the intermediate portions of) the linking parts 13d and 14d.

The above-described configurations of the linking parts 13d and 14d are just one example. The linking parts 13d and 14d simply need to connect the wire bonding parts 13a and 14a and the electrode bonding parts 13c and 14c. The linking parts 13d and 14d may be, for example, arch-shaped with an R-shaped apex. Alternatively, the linking parts 13d and 14d may connect in a straight line the wire bonding parts 13a and 14a and the electrode bonding parts 13c and 14c, which are different in height.

The linking parts 13e and 14e have a flat plate-like shape. In plan view, the linking parts 13e and 14e integrally connect second ends of the electrode bonding parts 13c and 14c, located closer to the wire bonding parts 13b and 14b, and first ends of the wire bonding parts 13b and 14b, located closer to the electrode bonding parts 13c and 14c.

In lateral view, the linking parts 13e and 14e extend vertically upward (in the +Z direction) from the second ends of the electrode bonding parts 13c and 14c, located closer to the wire bonding parts 13b and 14b, to a predetermined height (fourth height), and bend at a right angle to the wire bonding part 13b and 14b sides. Then, the linking parts 13e and 14e extend toward the wire bonding parts 13b and 14b, bend above the first ends of the wire bonding parts 13b and 14b, located closer to the electrode bonding part 13c and 14c, and extend vertically downward (in the −Z direction) to a predetermined height (second height) to connect to the first ends of the wire bonding parts 13b and 14b. Note here that the second height is greater (i.e., higher) than the fourth height, and is also greater than the combined length of the fourth height and the thickness of the semiconductor chip 12 (in the +Z direction). That is, the electrode bonding parts 13c and 14c are located higher in position (in the +Z direction) than the wire bonding parts 13b and 14b. The intermediate portions of the linking parts 13e and 14e are parallel to the main surface of the insulated circuit board 11. The intermediate portions of the linking parts 13e and 14e may be flush with the intermediate portions of the linking parts 13d and 14d. Note that the second height is a predetermined height from the wire bonding parts 13b and 14b to (the intermediate portions of) the linking parts 13e and 14e, and the fourth height is a predetermined height from the electrode bonding parts 13c and 14c to (the intermediate portions of) the linking parts 13e and 14e.

The above-described configurations of the linking parts 13e and 14e are just one example. The linking parts 13e and 14e simply need to connect the electrode bonding parts 13c and 14c and the wire bonding parts 13b and 14b. The linking parts 13e and 14e may be, for example, arch-shaped with an R-shaped apex. Alternatively, the linking parts 13e and 14e may connect in a straight line the electrode bonding parts 13c and 14c and the wire bonding parts 13b and 14b, which are different in height.

The lead frames 13 and 14 described above are each in a straight line in plan view. Therefore, the wire bonding parts 13a and 14a, the electrode bonding parts 13c and 14c, and the wire bonding parts 13b and 14b are also arranged in a line. In this case, the electrode bonding parts 13c and 14c may be located midway between the wire bonding parts 13a and 14a and the wire bonding parts 13b and 14b. Hence, the linking parts 13d and 14d and the linking parts 13e and 14e may have the same length in plan view.

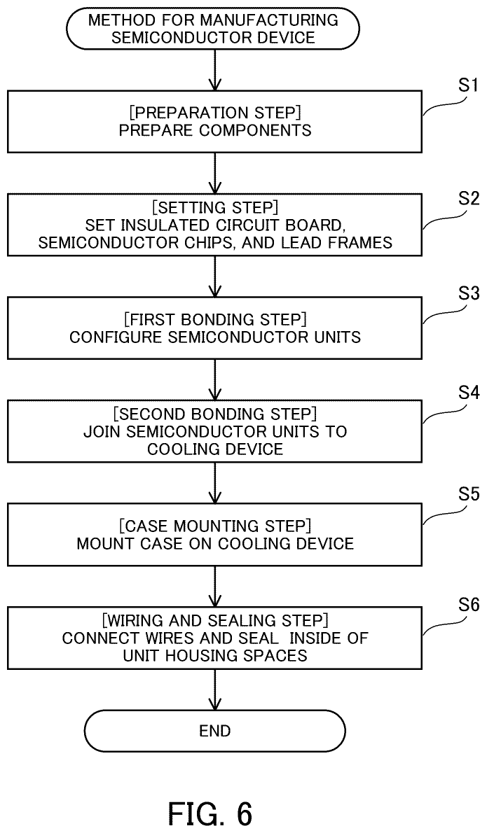

Next described is a method for manufacturing the semiconductor device 1 with reference to FIG. 6. FIG. 6 is a flowchart illustrating the method for manufacturing the semiconductor device of the first embodiment. First, a preparation step is performed to prepare components of the semiconductor device 1 (step S1 in FIG. 6). Examples of the components to be prepared include the insulated circuit board 11, the semiconductor chips 12, the cooling device 3, the case 20, and the lead frames 13 and 14. Other than these, components needed for the semiconductor device 1 may be prepared. A manufacturing device used to manufacture the semiconductor device 1 may also be prepared. The insulated circuit board 11 prepared here is described next with reference to FIG. 7. FIG. 7 is a plan view of the insulated circuit board included in the semiconductor device of the first embodiment.

The insulated circuit board 11 includes the insulating plate 11a, the conductive plates 11b, 11c, and 11d, and the metal plate 11e (see FIGS. 4 and 5), as described above. The conductive plates 11b, 11c, and 11d are formed on the front surface of the insulating plate 11a, as illustrated in FIG. 7.

The chip area 11b3 in which the semiconductor chip 12 is to be placed is provided approximately in the center of the conductive plate 11b. The conductive plate 11b has the recess 11b1 at its edge on the opposite side (the +X direction side) of the chip area 11b3 from the conductive plate 11c. The supporting conductive plate 11b2 is formed in the recess 11b1.

The chip area 11c3 in which the semiconductor chip 12 is to be placed is provided approximately in the center of the conductive plate 11c. The conductive plate 11c has the recess 11c1 at its edge on the opposite side (the +Y direction side) of the chip area 11c3 from the conductive plate 11d. The supporting conductive plate 11c2 is formed in the recess 11c1. The conductive plate 11d is formed in a region surrounded by the conductive plates 11b and 11c on the front surface of the insulating plate 11a.

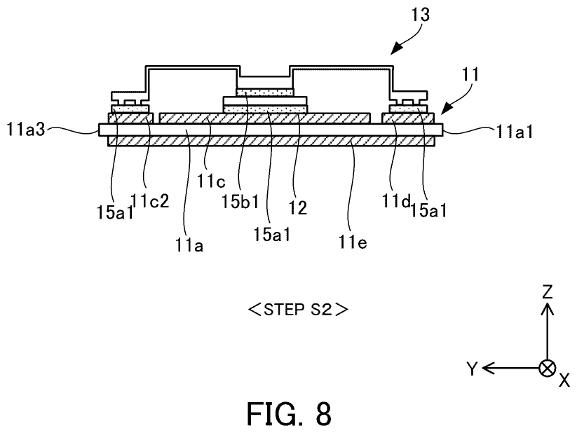

Next, a setting step is performed in which the insulated circuit board 11, the semiconductor chips 12, and the lead frames 13 and 14 are sequentially stacked and set (step S2 in FIG. 6). The setting step is described with reference to FIGS. 7 and 8. FIG. 8 illustrates the setting step included in the method for manufacturing the semiconductor device of the first embodiment. FIG. 8 depicts a cross-sectional view of the set configuration after the setting step. The cross-sectional view of FIG. 8 is obtained at a position corresponding to FIG. 4. Note that the lead frame 13 is described next in detail; however, the same applies to the lead frame 14.

First, the semiconductor 12 chips are individually set in the chip areas 11b3 and 11c3 of the insulated circuit board 11 via bonding plates 15a1. Then, as illustrated in FIG. 8, the wire bonding part 13a, the electrode bonding part 13c, and the wire bonding part 13b of the lead frame 13 are set via the bonding plates 15a1, 15b1, and 15a1 on the supporting conductive plate 11c2, the main electrode 12b of the semiconductor chip 12 in the chip area 11c3, and the conductive plate 11d, respectively.

The wire bonding part 14a, the electrode bonding part 14c, and the wire bonding part 14b of the lead frame 14 are set via the bonding plates 15a1, 15b1, and 15a1 on the supporting conductive plate 11b2, the main electrode 12b of the semiconductor chip 12 in the chip area 11b3, and the conductive plate 11c, respectively. Note that the bonding plates 15a1 and 15b1 are plate-shaped and made of the same material as the bonding members 15a and 15b.

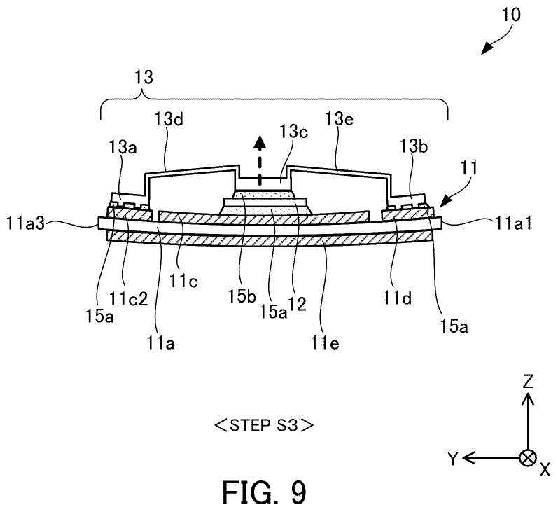

A first bonding step is performed next for bonding the insulated circuit board 11, the semiconductor chips 12, and the lead frames 13 and 14 (step S3 in FIG. 6). The first bonding step is described with reference to FIGS. 8 and 9. FIG. 9 illustrates the first bonding step included in the method for manufacturing the semiconductor device according to the first embodiment. A cross-sectional view of FIG. 9 is obtained at the same position as FIG. 8. Note that the following description is directed to the lead frame 13; however, the lead frame 14 also undergoes the first bonding step.

The insulated circuit board 11, the semiconductor chips 12, and the lead frames 13 and 14 set in step S2 are heated. At this time, the bonding plates 15a1 and 15b1 provided therebetween, as illustrated in FIG. 8, are also heated and become the molten bonding members 15a and 15b.

When heated, the insulated circuit board 11 warps due to differences in the thermal expansion coefficients of the insulating plate 11a, the conductive plates 11b, 11c, and 11d, and the metal plate 11e. The warp forms a downward convex, for example, when the metal plate 11e is positioned downwards.

Subsequently, heating is stopped and the molten bonding members 15a and 15b start to cure. In the lead frame 13, the wire bonding parts 13a and 13b start to be bonded to the supporting conductive plate 11c2 and the conductive plate 11d, respectively, by the bonding members 15a. In addition, the electrode bonding part 13c starts to be bonded to the main electrode 12b of the semiconductor chip 12 by the bonding member 15b.

In the lead frame 13 being bonded to the insulated circuit board 11 warped convex downward, the wire bonding parts 13a and 13b are being fixed to the supporting conductive palate 11c2 and the conductive plate 11d, respectively. Therefore, the lead frame 13 is supported by the two points of the wire bonding part 13a and the wire bonding part 13b serving as fulcrums. As a result, the lead frame 13 and the electrode bonding part 13c are suppressed from being inclined, which allows the thickness of the bonding member 15b to be maintained substantially uniform. The bonding member 15b is hardened while the thickness thereof is controlled to be uniform, whereby the electrode bonding part 13c and the main electrode 12b of the semiconductor chip 12 are bonded to each other. Bonding the electrode bonding part 13c to the main electrode 12b of the semiconductor chip 12 in this manner prevents the electrode bonding part 13c from tilting and therefore suppresses thickness variation in the bonding member 15b.

The wire bonding parts 13a and 13b include the multiple bosses 13a1 and 13b1. These bosses 13a1 and 13b1 maintain the thickness of the bonding members 15a between the wire bonding part 13a and the supporting conductive plate 11c2 and between the wire bonding part 13b and the conductive plate 11d substantially uniform. Thus, the semiconductor unit 10 is s configured through the above process.

Note that, in the first bonding step described here, the insulated circuit board 11, the semiconductor chips 12, and the lead frames 13 and 14 are bonded in one step. However, this case is only an example, and the semiconductor chips 12 may be bonded to the insulated circuit board 11 with the bonding members 15a, and then the lead frames 13 and 14 may be bonded to the insulated circuit board 11 and the semiconductor chips 12 with the bonding members 15b.

Next, a second bonding step is performed in which the semiconductor units 10 are bonded to the cooling device 3 (step S4 in FIG. 6). The semiconductor units 10a, 10b, and 10c are bonded to the front surface of the top plate 31 of the cooling device 3 along the longitudinal direction of the top plate 31 via bonding members (not illustrated).

Subsequently, a case mounting process is performed in which the case 20 is mounted on the cooling device 3 (step S5 in FIG. 6). The case 20 is mounted on the top plate 31 of the cooling device 3 with an adhesive (not illustrated). At this time, the semiconductor units 10a, 10b, and 10c on the top plate 31 are housed in the unit housing spaces 21e, 21f, and 21g, respectively, of the case 20.

Then, a wiring and sealing step is performed in which wiring connections are made for the semiconductor units 10a, 10b, and 10c housed in the case 20 and the inside of the unit housing spaces 21e, 21f, and 21g of the case 20 are then sealed (step S6 in FIG. 6).

First, in the semiconductor units 10a, 10b, and 10c housed in the unit housing spaces 21e, 21f, and 21g of the case 20, the control electrodes 12a of the semiconductor chips 12 and the inner ends of the control terminals 25a, 25b, and 25c are connected to each other by wires (not illustrated). In addition, the inner ends of the first connection terminals 22a, 22b, and 22c are individually bonded to the conductive plate 11b of the corresponding insulated circuit board 11. Similarly, the inner ends of the second connection terminals 23a, 23b, and 23c are individually bonded to the corresponding conductive plate 11d. Further, the inner ends of the U-phase output terminal 24a, the V-phase output terminal 24b, and the W-phase output terminal 24c are individually bonded to the corresponding conductive plate 11c.

Then, the unit housing spaces 21e, 21f, and 21g of the case 20 are filled with a sealing member (not illustrated) to seal the semiconductor units 10a, 10b, and 10c. In this manner, the semiconductor device 1 illustrated in FIGS. 1 and 2 is obtained.

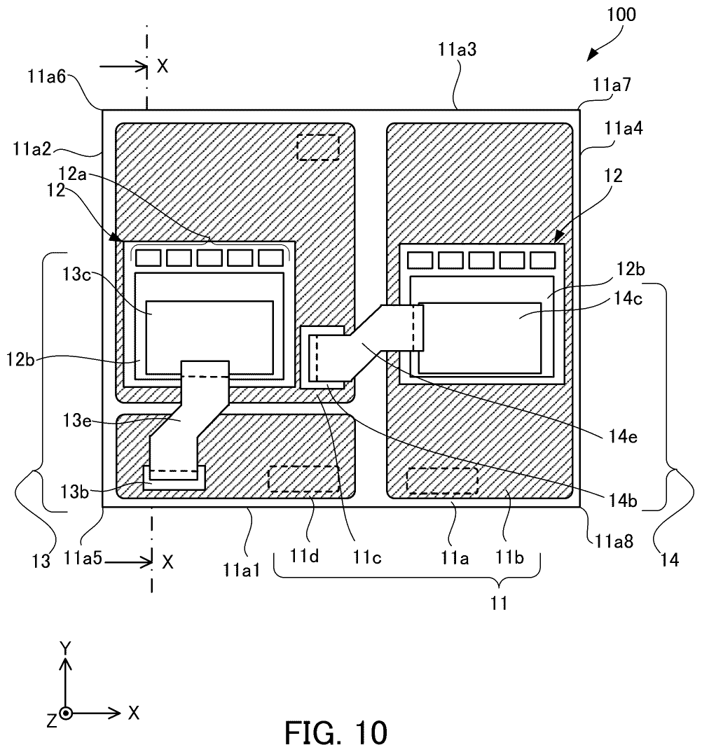

A semiconductor device of a reference example is described next. The semiconductor device of the reference example has a similar configuration to the semiconductor device 1 except for the semiconductor units 10. The semiconductor units included in the semiconductor device of the reference example are different from the semiconductor units 10 included in the semiconductor device 1 of the first embodiment. Here, the semiconductor units included in the semiconductor device of the reference example are described with reference to FIG. 10. FIG. 10 is a plan view of a semiconductor unit included in the semiconductor device of the reference example. Note that FIG. 10 corresponds to FIG. 3 of the first embodiment.

A semiconductor unit 100 of the reference example includes the insulated circuit board 11, the semiconductor chips 12, and the lead frames 13 and 14, as in the semiconductor unit 10 of the first embodiment. Note however that the conductive plates 11b and 11c included in the insulated circuit board 11 do not have the recesses 11b1 and 11c1 and do not therefore include the supporting conductive plates 11b2 and 11c2.

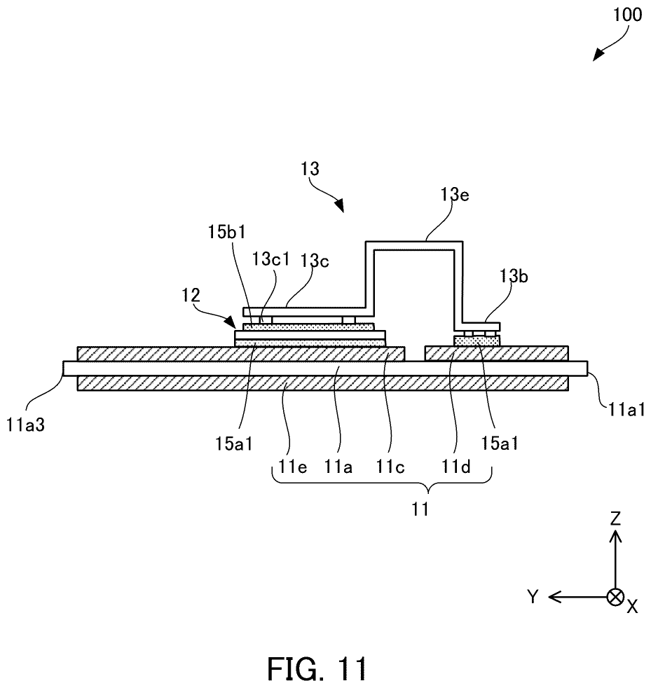

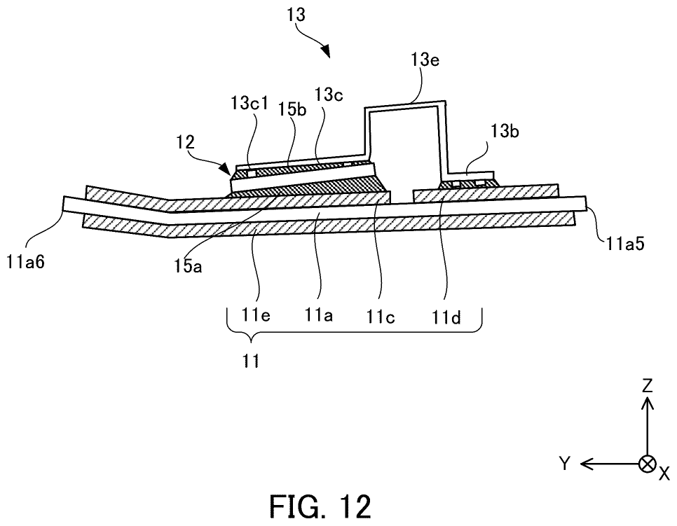

Accordingly, the lead frames 13 and 14 include the wire bonding parts 13b and 14b, the electrode bonding parts 13c and 14c, and the linking parts 13e and 14e connecting the former two parts. That is, the lead frames 13 and 14 do not include the wire bonding parts 13a and 14a and the linking parts 13d and 14d of the first embodiment. In addition, in the reference example, bosses are formed on the rear surfaces of the electrode bonding parts 13c and 14c (bosses 13c1 are illustrated in FIGS. 11 and 12). The wire bonding parts 13b and 14b are bonded to the conductive plates 11d and 11c via the bonding members 15a. The electrode bonding parts 13c and 14c are bonded to the main electrodes 12b of the semiconductor chips 12 via the bonding members 15b. Note that the semiconductor chips 12 are individually bonded to the conductive plates 11c and 11b via the bonding members 15a.

A semiconductor device including the above-described semiconductor units 100 may also be manufactured according to the flowchart of FIG. 6. Next, a method for manufacturing the semiconductor device is described with reference to FIG. 6. Note that, in the following manufacturing method, the same steps as those in the first embodiment are not described or are described briefly.

First, a preparation step is performed to prepare components of the semiconductor device of the reference example (step S1 in FIG. 6), as in the first embodiment. Then, a setting step is performed to sequentially set the insulated circuit board 11, the semiconductor chips 12, and the lead frames 13 and 14 (step S2 in FIG. 6). The setting step is described with reference to FIG. 11. FIG. 11 illustrates the setting step included in the method for manufacturing the semiconductor device of the reference example. Note that FIG. 11 depicts a cross-sectional view of the set configuration obtained after the setting step. The cross-sectional view of FIG. 11 is taken at a cut location along the dashed-dotted line X-X of FIG. 10.

Also in this case, the semiconductor chips 12 are set via the bonding plates 15a1 in the chip areas (not illustrated) of the insulated circuit board 11. Furthermore, as illustrated in FIG. 11, the electrode bonding part 13c and the wire bonding part 13b of the lead frame 13 are set via the bonding plates 15b1 on the main electrode 12b of the semiconductor chip 12 the conductive plate 11d, respectively.

Next, a first bonding step is performed for sequentially bonding the insulated circuit board 11, the semiconductor chips 12, and the lead frames 13 and 14 (step S3 in FIG. 6). The first bonding step is described with reference to FIGS. 11 and 12. FIG. 12 illustrates the first bonding step included in the method for manufacturing the semiconductor device of the reference example. A cross-sectional view of FIG. 12 is taken at the same cut location as FIG. 11. Note that the following description is directed to the lead frame 13; however, the same applies to the lead frame 14.

The insulated circuit board 11, the semiconductor chips 12, and the lead frames 13 and 14 set in step S2 are heated. At this time, the bonding plates 15a1 and 15b1 provided therebetween, as illustrated in FIG. 11, are also heated and become the molten bonding members 15a and 15b.

When heated, the insulated circuit board 11 warps due to differences in the thermal expansion coefficients of the insulating plate 11a, the conductive plates 11b, 11c, and 11d, and the metal plate 11e. The warp forms a downward convex, for example, when the metal plate 11e is positioned downwards.

Subsequently, heating is stopped and the molten bonding members 15a and 15b start to cure. In the lead frame 13, the wire bonding part 13b starts to be bonded to the conductive plate 11d by the bonding member 15a. Furthermore, the electrode bonding part 13c starts to be bonded to the main electrode 12b of the semiconductor chip 12 by the bonding member 15b.

Since the insulated circuit board 11 is warped downward, the electrode bonding part 13c of the lead frame 13 bonded to the insulated circuit board 11 fails to suppress tilting even if the bosses 13c1 are provided. This causes variation in the thickness of the bonding member 15b, which in turn causes the semiconductor chip 12 to tilt and thus entails variation in the thickness of the bonding member 15a.

When there is variation in the thickness of the bonding member 15b and the electrode bonding part 13c is connected to the main electrode 12b of the semiconductor chip 12 at an angle, there is a risk of variation in the heat dissipation of the semiconductor chip 12. The variation in heat dissipation may reduce the cooling performance and cause a failure of the semiconductor chip 12. Note that subsequently steps S4, S5, and S6 in FIG. 6 are performed in order to obtain a semiconductor device including the semiconductor units 100 of the reference example.

The above-described semiconductor device 1 includes the semiconductor units 10. Each of the semiconductor units 10 includes the semiconductor chip 12 including the main electrode 12b on its front surface; the conductive plate 11c (an example of the first conductive plate) having, on its front surface, the chip area 11c3 to which the rear surface of the semiconductor chip 12 is bonded; the conductive plate 11d (an example of the second conductive plate) provided adjacent to the conductive plate 11c in plan view; the supporting conductive plate 11c2 (an example of the supporting part) provided on the opposite side of the chip area 11c3 from the conductive plate 11d and insulated from the conductive plate 11c; and the lead frame 13 including the wire bonding part 13a (an example of the first bonding part) bonded to the supporting conductive plate 11c2, the wire bonding part 13b (an example of the second bonding part) bonded to the conductive plate 11d, and the electrode bonding part 13c bonded to the main electrode 12b of the semiconductor chip 12 via the bonding member 15b. In the above semiconductor unit 10, the lead frame 13 is supported at two points, i.e., the wire bonding parts 13a and 13b. This prevents the lead frame 13 from tilting, which in turn allows the thickness of the bonding member 15b to be maintained substantially uniform. The bonding member 15b is hardened while the thickness thereof is controlled to be uniform, whereby the electrode bonding part 13c and the main electrode 12b of the semiconductor chip 12 are bonded to each other. Bonding the electrode bonding part 13c to the main electrode 12b of the semiconductor chip 12 in this manner prevents the electrode bonding part 13c from tilting and suppresses thickness variation in the bonding member 15b. This prevents variation in the heat dissipation of the semiconductor chip 12, and reduces failures of the semiconductor chip 12, thereby preventing decreased reliability of the semiconductor device 1.

The supporting conductive plate 11c2 is disposed in the recess 11c1 (an example of the opening region) formed in the conductive plate 11c without being in contact with the conductive plate 11c. In such a configuration, the supporting conductive plate 11c2 may be used as a wiring path for an auxiliary emitter by connecting the control terminals 25a and the supporting conductive plate 11c2 with, for example, bonding wires. In addition, bonding the wire bonding part 13a of the lead frame 13 and the supporting conductive plate 11c2 increases the contact area of the lead frame 13 with the supporting conductive plate 11c2 compared to the structure depicted in FIG. 10, thereby improving heat dissipation.

In plan view, the lead frame 13 extends linearly from the electrode bonding part 13c to the wire bonding part 13a and also extends linearly from the electrode bonding part 13c to the wire bonding part 13b. That is, in plan view, the lead frame 13 extends linearly from the wire bonding part 13a to the wire bonding part 13b. This configuration enables the electrode bonding part 13c of the lead frame 13 to be raised above (i.e., set away in the +Z direction from) the semiconductor chip 12, which suppresses variation in the thickness of the bonding member 15b more reliably.

The lead frame 13 includes the linking part 13d (an example of the first linking part) having a flat plate-like shape and connecting between the electrode bonding part 13c and the wire bonding part 13a and the linking part 13e (an example of the second linking part) having a flat plate-like shape and connecting between the electrode bonding part 13c and the wire bonding part 13b. The first height from the wire bonding part 13a to the linking part 13d and the second height from the wire bonding part 13b to the linking part 13e are greater than the third height from the electrode bonding part 13c to the linking part 13d and the fourth height from the electrode bonding part 13c to the linking part 13e, respectively. It is preferable that the second height be greater than the combined length of the fourth height and the thickness of the semiconductor chip 12 (in the +Z direction) and the first height be greater than the combined length of the third height and the thickness of the semiconductor chip 12 (in the +Z direction). It is more preferable that the first height and the second height be equal and the third height and the fourth height be equal. The above-described configuration allows the electrode bonding part 13c to be more reliably raised above (set away in the +Z direction from) the semiconductor chip 12, thereby suppressing variation in the thickness of the bonding member 15b.

### Modification 1-1

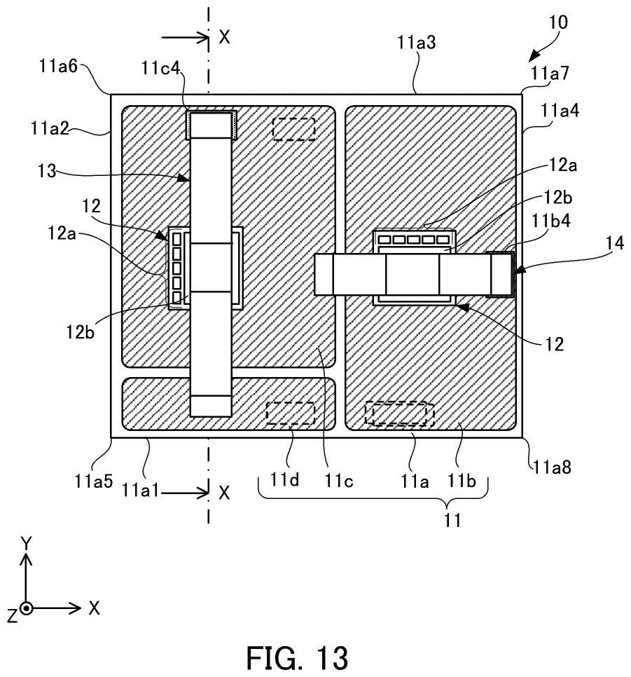

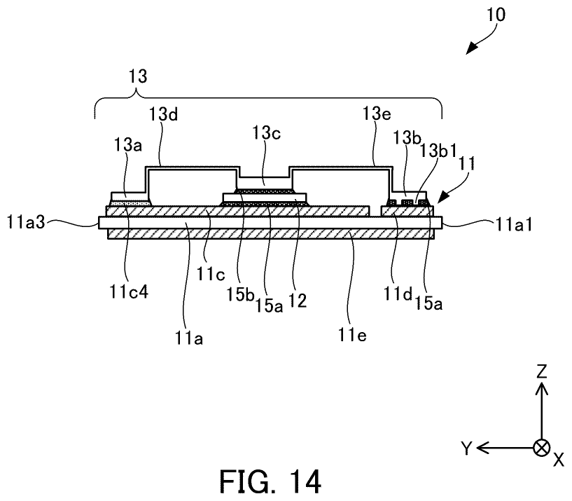

The semiconductor units 10 according to Modification 1-1 of the first embodiment are described with reference to FIGS. 13 and 14. FIG. 13 is a plan view of the semiconductor unit included in the semiconductor device of the first embodiment (Modification 1-1). FIG. 14 is a cross-sectional view of the semiconductor unit included in the semiconductor device of the first embodiment (Modification 1-1). Note that FIGS. 13 and 14 correspond to FIGS. 3 and 4, respectively, of the first embodiment. The cross-sectional view of FIG. 14 is taken along the dashed-dotted line X-X of FIG. 13.

The semiconductor device of Modification 1-1 is different from the semiconductor device 1 of the first embodiment in the semiconductor units 10. In each semiconductor unit 10 of Modification 1-1, the conductive plates 11b and 11c do not have the recesses 11b1 and 11c1 and do not therefore include the supporting conductive plates 11b2 and 11c2. That is, the conductive plates 11b and 11c of the semiconductor unit 10 of Modification 1-1 are provided with neither recesses nor openings and thus have flat, rectangular front surfaces.

In the above-described semiconductor unit 10 of Modification 1-1, the wire bonding parts 13a and 14a of the lead frames 13 and 14 are bonded to the conductive plates 11c and 11b via supporting block parts 11c4 and 11b4. For example, in the lead frame 13, the wire bonding part 13b is bonded to the conductive plate 11d with the bonding member 15a, as illustrated in FIG. 14. The wire bonding part 13a is supported by the supporting block part 11c4 placed on the conductive plate 11c. The wire bonding part 13a may be maintained at the same height as the wire bonding part 13b. The supporting block part 11c4 may be made of an insulating material. Such a material is resin, for example. The height of the supporting block part 11c4 simply needs to be such that the wire bonding part 13a is maintained at a predetermined height. As a result, the wire bonding part 13a is electrically insulated from the conductive plate 11c. In addition, the supporting block part 11c4 may be placed in the recess 11c1 provided in the conductive plate 11c in the same manner as in the first embodiment.

The rest of the configuration of the lead frame 13 of Modification 1-1 may be the same as that of the lead frame 13 of the first embodiment. In addition, the lead frame 14 of Modification 1-1 has the same configuration as the lead frame 13 of Modification 1-1.

Also in the semiconductor unit 10 of Modification 1-1, the electrode bonding part 13c is prevented from tilting, which suppresses variation in the thickness of the bonding member 15b, as in the first embodiment. Herewith, variation in heat dissipation of the semiconductor chip 12 is suppressed, thereby reducing the occurrence of failures of the semiconductor chip 12. This contributes to improved reliability of the semiconductor device 1.

### (b) SECOND EMBODIMENT

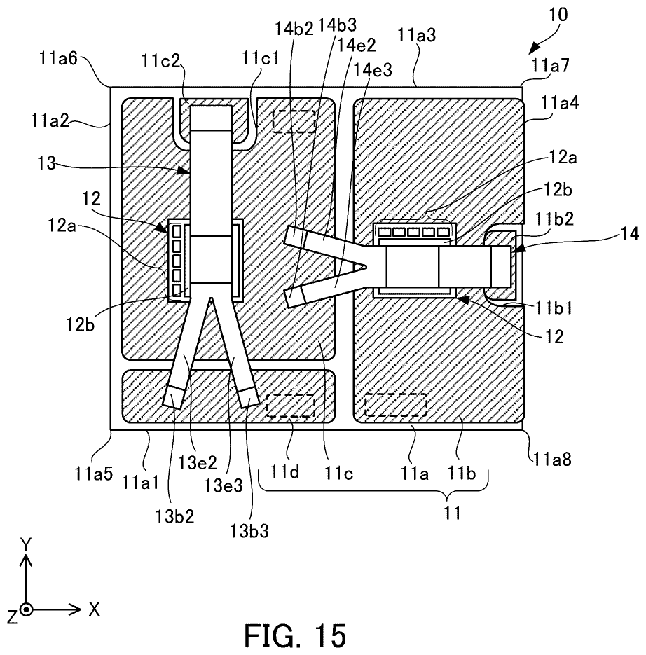

Next described is a second embodiment which is directed to a case where the lead frames 13 and 14 of the first embodiment are not linear in plan view, with reference to FIG. 15. FIG. 15 is a plan view of a semiconductor unit included in a semiconductor device of the second embodiment.

Each of the semiconductor units 10 of the second embodiment may have the same configuration as the semiconductor unit 10 of the first embodiment except for the lead frames 13 and 14. In the lead frames 13 and 14 of the second embodiment, the wire bonding parts 13b and 14b of the lead frames 13 and 14 of the first embodiment are split into wire bonding parts 13b2 and 13b3 (bonding subparts) and wire bonding parts 14b2 and 14b3 (bonding subparts). For the configurations of the lead frames 13 and 14 of the second embodiment, those of the lead frames 13 and 14 of FIGS. 4 and 5 may be referred to except for the wire bonding parts 13b2 and 13b3 and the wire bonding parts 14b2 and 14b3. The wire bonding parts 13b2 and 13b3 and the wire bonding parts 14b2 and 14b3 are respectively connected to the conductive plates 11d and 11c via the bonding members 15b.

Accordingly, the lead frames 13 and 14 of the second embodiment include linking parts 13e2 and 13e3 and linking parts 14e2 and 14e3. Each of the linking parts 13e2 and 13e3 and the linking parts 14e2 and 14e3 has a linear shape. The linking parts 13e2 and 13e3 connect the electrode bonding part 13c and the wire bonding parts 13b2 and 13b3, respectively. The linking parts 14e2 and 14e3 connect the electrode bonding part 14c and the wire bonding parts 14b2 and 14b3, respectively. Note also that the linking parts 13e2 and 13e3 and the linking parts 14e2 and 14e3 have the same length (the first and second lengths).

A semiconductor device including the above-described lead frames 13 and 14 may also be manufactured according to the flowchart of FIG. 6. In the first bonding step of step S3 of the flowchart of FIG. 6, when heating is stopped to then allow the molten bonding members 15a and 15b to cure, the electrode bonding parts 13c and 14c of the lead frames 13 and 14 are supported by the wire bonding parts 13a and 14a, the wire bonding parts 13b2 and 13b3, and the wire bonding parts 14b2 and 14b3. Therefore, according to the second embodiment, tilting of the lead frame 13 and the electrode bonding part 13c is more stably suppressed than in the first embodiment. This in turn contributes to maintain more substantially uniform thickness of each of the bonding members 15b.

The second embodiment described above is directed to an example where the lead frames 13 and 14 include the two-split wire bonding parts 13b2 and 13b3 and the two-split wire bonding parts 14b2 and 14b3, respectively.

Note that the wire bonding parts 13b and 14b of the lead frames 13 and 14 of the first embodiment may be split into not two, but three or more. In addition, the wire bonding parts 13a and 14a of the lead frames 13 and 14 of the first embodiment may be split into two or more. In this case, openings and recesses are formed in the conductive plates 11c and 11b according to the number of splits of the wire bonding parts 13a and 14a. Alternatively, the wire bonding parts split into two or more may be individually bonded to the conductive plates 11c and 11b via the supporting block parts of Modification 1-1.

When at least one side of the individual lead frames 13 and 14 of the first embodiment, that is, at least either the wire bonding parts 13a and 14a or the wire bonding parts 13b and 14b, are split into multiple pieces, the electrode bonding parts 13c and 14c may be provided at the positions of the centers of gravity of the lead frames 13 and 14. Herewith, when the lead frames 13 and 14 are bonded to the insulated circuit board 11 and the semiconductor chips 12 (step S3 in FIG. 6), it is possible to suppress tilting of the lead frames 13 and 14 and the electrode bonding parts 13c and 14c more stably. This in turn contributes to maintain substantially uniform thickness of each of the bonding members 15b more reliably.

### (c) THIRD EMBODIMENT

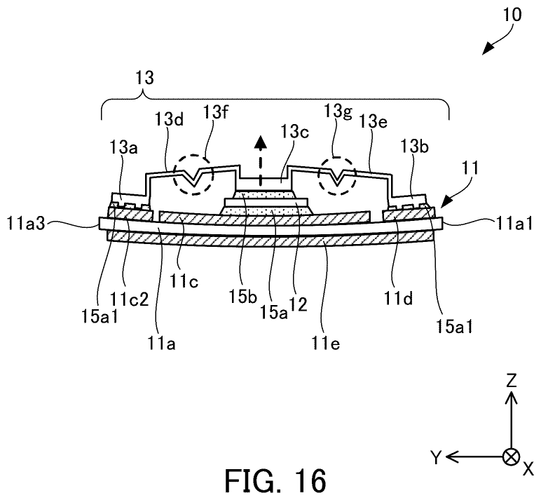

Next described is a third embodiment which is directed to a case where the lead frames 13 and 14 included in the semiconductor unit 10 of the first embodiment include elastic portions, with reference to FIG. 16. FIG. 16 illustrates a first bonding step included in the method for manufacturing a semiconductor device of the third embodiment. Note that the semiconductor device of the third embodiment may also be manufactured according to the flowchart of FIG. 6 of the first embodiment.

Each semiconductor unit 10 of the third embodiment is configured by including elastic portions 13f and 13g in the lead frame 13 of the semiconductor unit 10 of the first embodiment. Otherwise, the semiconductor unit 10 of the third embodiment has the same configuration as the semiconductor unit 10 of the first embodiment. The lead frame 14 of the semiconductor unit 10 of the third embodiment also has the same configuration as the lead frame 13 of the third embodiment.

In this case, the elastic portions 13f and 13g included in the flat, plate-like linking parts 13d and 13e of the lead frame 13 each have a concave shape in which the entire widths of the linking parts 13d and 13e are bent in either the +Z direction of the thickness direction. The elastic portions 13f and 13g are indicated by the circles with dashed lines in FIG. 16. FIG. 16 depicts a case where the linking parts 13d and 13e are each provided with one concave elastic portion, that is, the elastic portions 13f and 13g, respectively; however, two or more elastic portions 13f and 13g may be provided to each of the linking parts 13d and 13e. The elastic portions 13f and 13g may have other shapes than concave as long as they exhibit elasticity in the linking parts 13d and 13e. The lead frame 14 may also include similar elastic portions.

Thus, when the lead frames 13 and 14 include elastic portions, the electrode bonding parts 13c and 14c may be provided at the positions of the centers of gravity of the lead frames 13 and 14, as in the second embodiment. When the lead frames 13 and 14 are bonded to the insulated circuit board 11 and the semiconductor chips 12 (step S3 in FIG. 6), it is possible to suppress tilting of the lead frames 13 and 14 and the electrode bonding parts 13c and 14c more stably. This in turn contributes to maintain substantially uniform thickness of each of the bonding members 15b more reliably.

In addition, the semiconductor device including the above-described semiconductor units 10 has the advantage that, when the semiconductor device is manufactured according to the flowchart of FIG. 6, the elastic portions mitigate possible external impacts applied to the semiconductor units 10 during the first bonding step of step S3 and the wiring and sealing step of step S6. Therefore, it is possible to prevent the electrode bonding parts 13c and 14c of the lead frames 13 and 14 from separating from the semiconductor chips 12.

The disclosed techniques allow for maintaining uniform thickness of each bonding member that bonds the front surface of a semiconductor chip and a lead frame.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip including a main electrode on a front surface thereof;
a first conductive plate having a first main surface with a chip area defined thereon, a rear surface of the semiconductor chip being bonded to the chip area;
a second conductive plate provided adjacent to the first conductive plate in a plan view of the semiconductor device;
a supporting part provided adjacent to the first conductive plate in the plan view, and being insulated from the first conductive plate, the supporting part and the second conductive plate being on two opposite sides of the chip area; and
a lead frame, including
a first bonding part bonded to the supporting part,
a second bonding part bonded to the second conductive plate, and
an electrode bonding part bonded to the main electrode of the semiconductor chip via a bonding member.

2. The semiconductor device according to claim 1, wherein
the first conductive plate has a recess that defines an opening region in the plan view,
the supporting part is disposed in the opening region, and
the supporting part is spaced apart from the first conductive plate.

3. The semiconductor device according to claim 2, wherein the supporting part is made of a same material as the first conductive plate.

4. The semiconductor device according to claim 1, wherein, in the lead frame, a first length spanning from the electrode bonding part to the first bonding part is equal to a second length spanning from the electrode bonding part to the second bonding part.

5. The semiconductor device according to claim 1, wherein:
the lead frame further includes:
a first linking part of a plate shape, connecting between the electrode bonding part and the first bonding part, and
a second linking part of the plate shape, connecting between the electrode bonding part and the second bonding part, and
a first height spanning from the first bonding part to the first linking part and a second height spanning from the second bonding part to the second linking part are greater than a third height spanning from the electrode bonding part to the first linking part and a fourth height spanning from the electrode bonding part to the second linking part, respectively.

6. The semiconductor device according to claim 1, wherein the lead frame extends linearly from the electrode bonding part to the first bonding part in the plan view.

7. The semiconductor device according to claim 6, wherein the lead frame extends linearly from the electrode bonding part to the second bonding part in the plan view.

8. The semiconductor device according to claim 6, wherein the lead frame extends linearly from the first bonding part to the second bonding part in the plan view.

9. The semiconductor device according to claim 6, wherein
the second bonding part includes a plurality of second bonding subparts, and
the lead frame extends linearly from the electrode bonding part to each of the plurality of second bonding subparts in the plan view.

10. The semiconductor device according to claim 9, wherein the electrode bonding part is located at a position corresponding to a center of gravity of the lead frame in the plan view.

11. The semiconductor device according to claim 1, wherein the lead frame further includes a first elastic portion between the electrode bonding part and the first bonding part and a second elastic portion between the electrode bonding part and the second bonding part.

12. The semiconductor device according to claim 11, wherein:
the lead frame further includes
a first linking part of a plate shape, connecting between the electrode bonding part and the first bonding part, and
a second linking part of the plate shape, connecting between the electrode bonding part and the second bonding part,
the first and second elastic portions are respectively provided in the first linking part and the second linking part,
in the first elastic portion, the first linking part has a first bent portion that is of an entire width of the first linking part, and is bent in a thickness direction of the first linking part, and
in the second elastic portion, the second linking part has a second bent portion that is of an entire width of the second linking part, and is bent in a thickness direction of the second linking part.
